(19) United States
(12) Patent Application Publication
(10) Pub. No.: US 2024/0412960 A1
(43) Pub. Date: Dec. 12, 2024

(54) SENSOR DEVICE AND SEMICONDUCTOR PROCESSING APPARATUS USING THE SAME

(71) Applicant: SAMSUNG ELECTRONICS CO., LTD., Suwon-si (KR)

(72) Inventors: Jawon KO, Suwon-si (KR); Jongwha LEE, Suwon-si (KR); Taijo JEON, Suwon-si (KR); Yunsong JEONG, Suwon-si (KR); Jaesup LEE, Suwon-si (KR); Solhee IN, Suwon-si (KR)

(21) Appl. No.: 18/404,645

(22) Filed: Jan. 4, 2024

(30) Foreign Application Priority Data
Jun. 9, 2023 (KR) 10-2023-0074414

(51) Int. Cl. H01J 37/32

(52) U.S. Cl. CPC H01J 37/32981; H01J 37/3211; H01J 37/32183; H01J 37/32972; H01J 37/3299

(57) ABSTRACT

A sensor device includes a first substrate, a second substrate on the first substrate, a plurality of detection units between the first substrate and the second substrate and configured to collect detection information from plasma formed in a space above the second substrate, a controller configured to generate characteristic data representing characteristics of the plasma based on the detection information collected by the plurality of detection units, and a power supply unit including a radio frequency (RF) energy harvester configured to produce power for operation of at least one of the plurality of detection units and the controller from RF power used to form the plasma.

### CROSS-REFERENCE TO RELATED APPLICATION(S)

This application claims benefit of and priority to Korean Patent Application No. 10-2023-0074414 filed on Jun. 9, 2023 in the Korean Intellectual Property Office, the disclosure of which is incorporated herein by reference in its entirety.

### BACKGROUND

The present inventive concept relates to a sensor device and a semiconductor processing apparatus using the same.

In a semiconductor processing apparatus performing semiconductor processing using plasma, it may be necessary to accurately control the uniformity of plasma formed on a processing target, such as a wafer, to improve yield. Various attempts have been made to improve the uniformity of plasma, and methods to increase the efficiency of semiconductor processes by immediately measuring the uniformity of plasma have been proposed. Control variables of the semiconductor processing apparatus may be adjusted, while observing plasma through a view port of the semiconductor processing apparatus. However, it may be difficult to accurately determine the uniformity of plasma by observing plasma through the view port, and thus, the uniformity of plasma may not be accurately controlled during an actual semiconductor process.

### SUMMARY

An aspect of the present inventive concept is to provide a sensor device and a semiconductor processing apparatus using the same, capable of minimizing problems caused by an internal battery, by including an RF energy harvester in the sensor device introduced into the semiconductor processing apparatus and used to analyze characteristics of plasma and producing power using RF energy for forming plasma.

According to an aspect of the present inventive concept, a sensor device may include a first substrate, a second substrate on the first substrate, a plurality of detection units between the first substrate and the second substrate and configured to collect detection information from plasma formed in a space above the second substrate, a controller configured to generate characteristic data representing characteristics of the plasma based on the detection information collected by the plurality of detection units, and a power supply unit including a radio frequency (RF) energy harvester configured to produce power for operation of at least one of the plurality of detection units and the controller from RF power used to form the plasma.

According to another aspect of the present inventive concept, a sensor device may include a first substrate, a second substrate on the first substrate, a coil pattern between the first substrate and the second substrate, wherein the coil pattern is configured to convert radio frequency (RF) power for forming plasma on the second substrate into an AC voltage, a voltage generating circuit connected to the coil pattern and configured to convert the AC voltage into a DC voltage, and a controller configured to receive the DC voltage output from the voltage generating circuit and generate characteristic data representing characteristics of the plasma.

According to another aspect of the present inventive concept, a semiconductor processing apparatus may include a chamber, a first bias electrode and a second bias electrode in a space inside the chamber, an electrostatic chuck above the first bias electrode, and a control device configured to control the first bias electrode, the second bias electrode, and the electrostatic chuck, wherein the control device is configured to supply radio frequency (RF) power to each of the first bias electrode and the second bias electrode to form plasma in a space inside the chamber, wherein the control device is configured to control the first bias electrode, the second bias electrode, and the electrostatic chuck using characteristic data generated by a sensor device on the electrostatic chuck, wherein the characteristic data represents characteristics of the plasma, and wherein the sensor device includes an RF energy harvester configured to produce power from the RF power used to form the plasma.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic diagram illustrating a semiconductor processing system according to an embodiment of the present inventive concept;

FIG. 2 is a schematic diagram of a semiconductor processing apparatus according to an embodiment of the present inventive concept;

FIGS. 3 to 5 are diagrams schematically illustrating a sensor device according to an embodiment of the present inventive concept;

FIG. 6 is a diagram schematically illustrating an RF energy harvester included in a sensor device according to an embodiment of the present inventive concept;

FIGS. 7 to 11 are diagrams schematically illustrating sensor devices according to embodiments of the present inventive concept;

FIG. 12 is a flowchart illustrating a method for controlling semiconductor processing according to an embodiment of the present inventive concept;

FIGS. 13 and 14 are diagrams illustrating an operation of a sensor device according to an embodiment of the present inventive concept;

FIG. 15 is a diagram schematically illustrating characteristic data generated by a sensor device according to an embodiment of the present inventive concept; and

FIGS. 16 to 18 are diagrams illustrating an operation of a semiconductor processing apparatus according to an exemplary embodiment of the present inventive concept.

### DETAILED DESCRIPTION

Hereinafter, example embodiments of the present inventive concept will be described above with reference to the accompanying drawings.

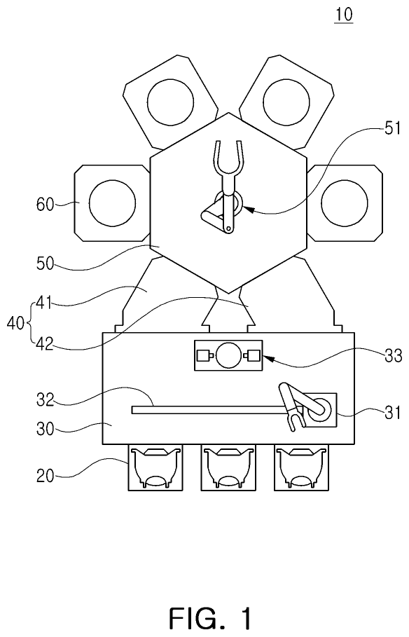

FIG. 1 is a schematic diagram illustrating a semiconductor processing system according to an embodiment of the present inventive concept.

Referring to FIG. 1, a semiconductor processing system 10 according to an embodiment of the present inventive concept may include a wafer transfer device 30, a load lock chamber 40, a transfer chamber 50, and a plurality of semiconductor processing apparatuses 60, and the like. For example, the wafer transfer device 30 may receive a wafer through a container, such as a front open unified pod (FOUP) 20 inside a line where the semiconductor processing system 10 is disposed. The wafer transfer device 30 may transfer a wafer received through the FOUP 20 to the load lock chamber 40, or receive a wafer on which semiconductor processing has been completed in the plurality of semiconductor processing apparatuses 60 from the load lock chamber 40 and accommodate the wafer in the FOUP 20.

The wafer transfer device 30 may include a wafer transfer robot 31 having an arm capable of gripping a wafer, a rail unit 32 moving the wafer transfer robot 31, and an aligner 33 aligning a wafer, and the like. Assuming an operation of transferring a wafer from the FOUP 20 to the load lock chamber 40, the wafer transfer robot 31 may take out the wafer stored in the FOUP 20 and place the wafer on the aligner 33. The aligner 33 may rotate the wafer to align the wafer in a predetermined direction. When wafer alignment is completed in the aligner 33, the wafer transfer robot 31 may take the wafer out of the aligner 33 and move the wafer to the load lock chamber 40.

The load lock chamber 40 may include a loading chamber 41 connected to the wafer transfer device 30 and allowing wafers loaded into the semiconductor processing apparatus 60 to temporarily stay therein for semiconductor processing and an unloading chamber 42 in which wafers completed in processing and loaded out of the process chamber 60 temporarily stay. When the wafers aligned in the aligner 33 are loaded into the loading chamber 41, the inside of the loading chamber 41 may be depressurized to prevent external contaminants from entering.

The load lock chamber 40 may be connected to the transfer chamber 50, and the plurality of semiconductor processing apparatuses 60 may be connected around the transfer chamber 50. A wafer transfer robot 51 may be disposed inside the transfer chamber 50 to transfer wafers between the load lock chamber 40 and the plurality of process chambers 60. The wafer transfer robot 31 of the wafer transfer device 30 may be referred to as a first wafer transfer robot, and a wafer transfer robot 51 of the transfer chamber 50 may be referred to as a second wafer transfer robot.

Each of the plurality of semiconductor processing apparatuses 60 may perform semiconductor processing on a wafer. For example, a semiconductor processing performed by the plurality of semiconductor processing apparatuses 60 may include a deposition process, an etching process, an exposure process, an annealing process, a polishing process, an ion implantation process, and the like.

Plasma may be formed inside at least one of the plurality of semiconductor processing apparatuses 60 in order to perform at least some of the afore-mentioned semiconductor processes. Plasma may be formed on a wafer, a mask, a mother substrate for a display, etc., which are subject to semiconductor processing, and the yield of the process may vary depending on how plasma is formed. Therefore, prior to actually performing semiconductor processing by the semiconductor processing apparatuses 60, an operation of forming plasma and analyzing characteristics thereof may precede.

In an embodiment of the present inventive concept, the characteristics of plasma formed in the semiconductor processing apparatuses 60 may be analyzed using a sensor device having a shape, such as a wafer, a mask, a mother substrate for a display, and the like, which are processing objects. For example, the sensor device may include a plurality of detection units installed at a plurality of different positions to collect detection information from plasma and a controller generating characteristic data representing the characteristics of plasma based on the detection information.

For example, the plurality of detection units may collect the temperature of the plasma, vibrations of the plasma, the intensity of light emitted from the plasma, and the like as detection information. The controller may generate characteristic data representing characteristics of plasma in various forms based on the detection information, and for example, may generate the density or temperature distribution of plasma in the form of two-dimensional image data.

In the sensor device, power necessary for the operation of the plurality of detection units and the controller may be supplied by a battery of the sensor device itself. However, since an internal space of the semiconductor processing apparatuses 60 is maintained in an environment of very low air pressure and high temperature while plasma is formed, problems, such as expansion and damage of the battery, may arise.

In an embodiment of the present inventive concept, an RF energy harvester that generates power from radio frequency (RF) power supplied to the semiconductor processing apparatuses 60 to form plasma may be included in the sensor device. Since the RF energy harvester may generate power while RF power is supplied to the semiconductor processing apparatuses 60, the sensor device may be implemented even with a small-capacity battery, or the battery may be omitted from the sensor device according to embodiments. Therefore, the problem of the occurrence of an error in the operation of the sensor device due to damage to the battery or the like while the semiconductor processing apparatuses 60 are operating may be prevented.

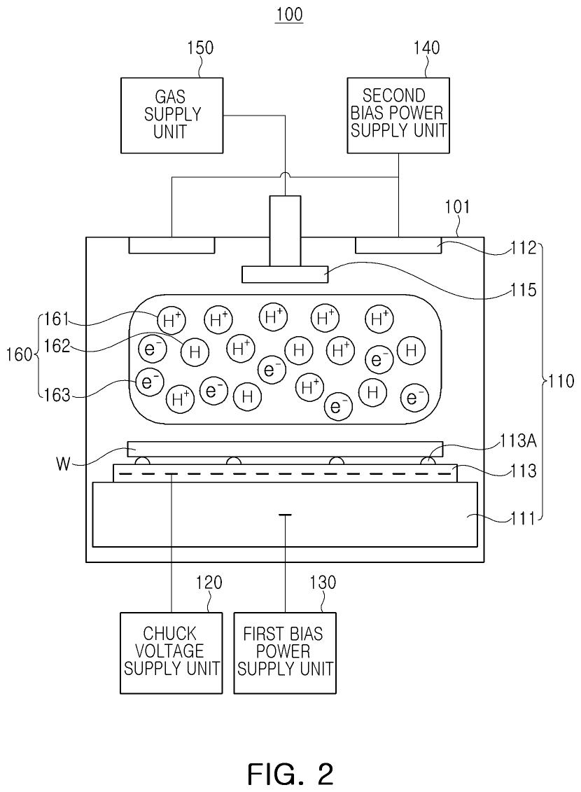

FIG. 2 is a schematic diagram of a semiconductor processing apparatus according to an embodiment of the present inventive concept.

A semiconductor processing apparatus 100 according to an embodiment of the present inventive concept may be an apparatus of performing semiconductor processing using plasma. The semiconductor processing apparatus 100 may include a chamber 110, a chuck voltage supply unit 120, a first bias power supply unit 130, a second bias power supply unit 140, and a gas supply unit 150.

The chamber 110 may include a housing 101, a first bias electrode 111, a second bias electrode 112, an electrostatic chuck 113, and a gas flow path 115. A processing target on which semiconductor processing is to be performed may be seated on the electrostatic chuck 113. In an embodiment illustrated in FIG. 2, the processing target is illustrated as a wafer W, but the processing target may be changed to a mother substrate for a display, a mask, and the like.

As illustrated in FIG. 2, a plurality of protrusions 113A having a protruding shape may be formed on an upper surface of the electrostatic chuck 113. The wafer W may be seated on the protrusion 113A, and thus, a space may be formed between an upper surface of the electrostatic chuck 113 and the wafer W. For example, a space between the upper surface of the electrostatic chuck 113 and the wafer W may be filled with helium gas or the like for the purpose of cooling the wafer W.

In an embodiment, the wafer W may be fixed on the electrostatic chuck 113 by a Coulomb force generated from the chuck voltage supplied to the electrostatic chuck 113 by the chuck voltage supply unit 20. For example, the chuck voltage supply unit 120 may supply the chuck voltage to the electrostatic chuck 113 in the form of a constant voltage, and the chuck voltage may have a magnitude of hundreds to thousands of volts.

In order to perform semiconductor processing, air may be removed from the inside of the chamber 110 to form an environment close to vacuum with an atmospheric pressure of about 1 mTorr, and a reactive gas may be introduced through the gas flow path 115. The first bias power supply unit 130 may supply a first bias power to the first bias electrode 111 located below the electrostatic chuck 113, and supply a second bias power to the second bias power supply unit 140 located above the electrostatic chuck 113. Each of the first bias power supply unit 130 and the second bias power supply unit 140 may include an RF power source for supplying bias power.

Plasma 160 including ions 161, radicals 162, and electrons 163 of the reactive gas is generated in the space above the wafer W by the first bias power and the second bias power, and the reactive gas may be activated by the plasma 160 to increase reactivity. For example, when the semiconductor processing apparatus 100 is an etching apparatus, the ions 161, the radicals 162, and the electrons 163 of the reactive gas may be accelerated to the wafer W by the first bias power supplied to the first bias electrode 111 by the first bias power supply unit 130. At least some of the semiconductor substrate or layers included in the wafer W may be dry-etched by the ions 161, the radicals 162, and the electrons 163 of the reaction gas.

Light is emitted in the process of stabilizing particles, such as ions 161, in the plasma 160, and the wavelength band of the emitted light may vary depending on the chemical species. Therefore, by detecting the intensity of light emitted from the plasma 160 in a predetermined wavelength band, characteristics, such as density and thickness of the plasma, may be detected.

In an embodiment of the present inventive concept, instead of the wafer W on which an etching process, a deposition process, etc., using the plasma 160 are performed, a separately manufactured sensor device may be disposed on the electrostatic chuck 113, and characteristics, such as a temperature distribution and density of the plasma 160 may be analyzed using the raw data collected by the sensor device. The sensor device may measure the intensity of light emitted from the plasma 160 and the temperature of the plasma 160.

The sensor device may include an RF energy harvester that generates power necessary for operation. The RF energy harvester may produce DC voltage power by using RF power supplied by each of the first bias power supply unit 130 and the second bias power supply unit 140. Accordingly, by implementing a small-capacity battery as a battery supplying power necessary for the operation of the sensor device or omitting the battery, problems, such as damage to the battery, may be prevented.

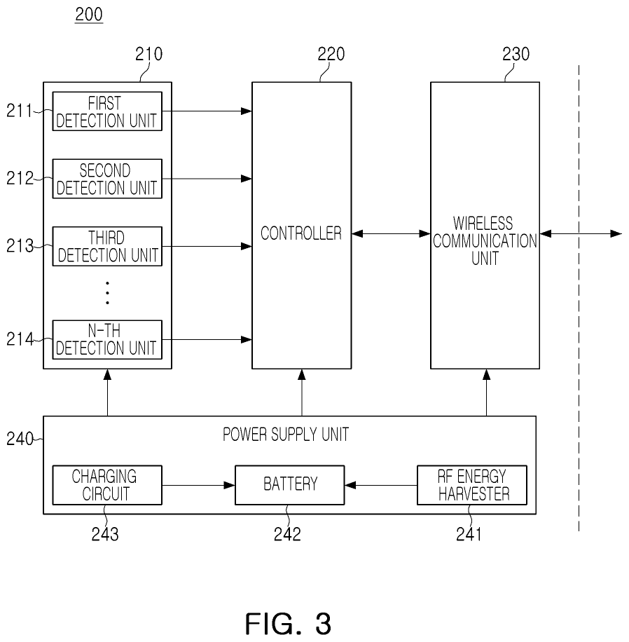

FIGS. 3 to 5 are schematic diagrams of a sensor device according to an embodiment of the present inventive concept.

Referring to FIG. 3, a sensor device 200 according to an embodiment of the present inventive concept may include a plurality of detection units 211 to 214: 210, a controller 220, a wireless communication unit 230, a power supply unit 240, and the like. When the sensor device is installed inside the semiconductor processing apparatus, plasma may be formed on the sensor device, and the plurality of detection units 210 may collect detection information, such as temperature, vibrations, and the intensity of light from different positions of the plasma. For example, the plurality of detection units 210 may collect the same type of detection information. However, according to embodiments, at least some of the plurality of detection units 210 may collect different types of detection information.

For example, when each of the plurality of detection units 210 collects the intensity of light emitted from the plasma as detection information, each of the plurality of detection units 210 may include a light guide and a photodetector coupled with the light guide. The photodetector is designed to detect the intensity of light in a specific wavelength band, and for example, the photodetector may detect the intensity of light in a wavelength band belonging to a range of 200 nm to 3 m.

In this case, the controller 220 may obtain the intensity of light emitted from a plurality of different regions of the plasma in various wavelength bands. The controller 240 may receive the intensity of light as detection information from the plurality of detection units 210 and generate characteristic data representing characteristics of plasma using the received detection information. According to embodiments, the controller 240 may process the detection information received from the plurality of detection units 210 and transmit the processed detection information externally through the wireless communication unit 230. In this case, an operation of generating characteristic data representing characteristics of plasma using detection information may be performed by another external device.

The power supply unit 240 may include an RF energy harvester 241, a battery 242, a charging circuit 243, and the like. The RF energy harvester 241 may generate power by using RF power supplied to the semiconductor processing apparatus to form plasma around the sensor device 200. The battery 242 may be charged by power produced by the RF energy harvester 241 and also charged by power supplied by the charging circuit 243. For example, the charging circuit 243 may include at least one of a wireless charging circuit and a wired charging circuit.

While the plurality of detection units 210 collect detection information from plasma, power necessary for the operation of the plurality of detection units 210 and the controller 220 may be supplied from the RF energy harvester 241 or the battery 242. For example, when the capacity of the battery 242 decreases below a predetermined reference capacity while the plurality of detection units 210 collects detection information, the controller 220 may control the power supply unit 240 so that the battery 242 is charged by power produced by the RF energy harvester 241 or power produced by the RF energy harvester 241 is directly supplied to the plurality of detection units 210 and the controller 220.

The charging circuit 243 may charge the battery 242 in a wired/wireless charging manner when the sensor device 200 is drawn out of the semiconductor processing apparatus and stored in separate management equipment. Alternatively, if the management equipment includes an RF module, RF power output by the RF module included in the management equipment may be converted into power by the RF energy harvester 241, and the battery 242 may be charged in the management equipment by the power produced by the RF energy harvester 241.

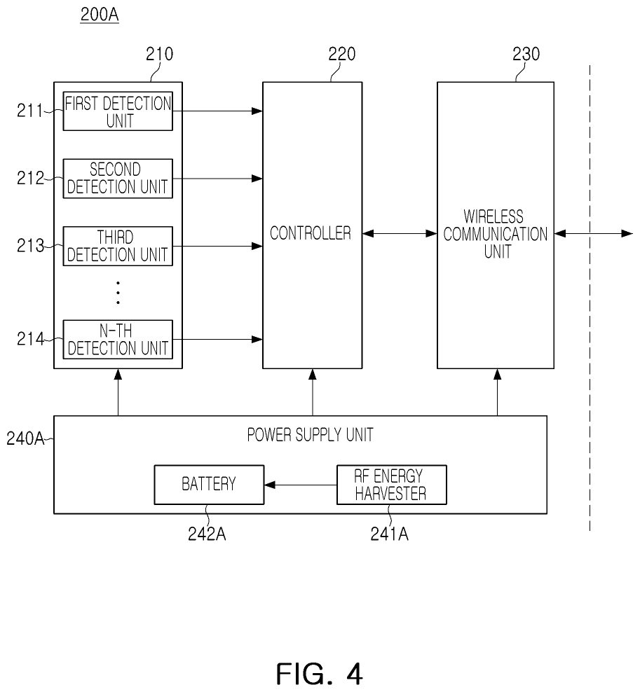

Next, referring to FIG. 4, a sensor device 200A according to an embodiment of the present inventive concept may include a plurality of detection units 211-214: 210, a controller 220, a wireless communication unit 230, a power supply unit 240A, and the like. Configurations and operations of the plurality of detection units 211 to 214: 210, the controller 220, and the wireless communication unit 230 may be similar to those described above with reference to FIG. 3.

In the sensor device 200A according to the embodiment illustrated in FIG. 4, the power supply unit 240A may include an RF energy harvester 241A and a battery 242A. While the plurality of detection units 210 collects detection information from plasma, power necessary for operation of the plurality of detection units 210 and the controller 220 may be supplied directly from the RF energy harvester 241A or the battery 242A. When the capacity of the battery 242A decreases below the reference capacity, the controller 220 may control the power supply unit 240A so that the RF energy harvester 241A directly supplies power or charges the battery 242A.

Since the power supply unit 240A does not have a separate charging circuit, in the sensor device 200A according to the embodiment illustrated in FIG. 4, the battery 242A may be charged only by the RF energy harvester 241A. For example, when the sensor device 200A in the semiconductor processing apparatus completes an operation of collecting detection information necessary to analyze the characteristics of plasma, the sensor device 200A may be received in the FOUP or the like and transferred to other management equipment. When the sensor device 200A is introduced into the management equipment, the management equipment may receive detection information collected by the sensor device 200A or characteristic data generated by the controller 220 from the detection information through the wireless communication unit 230 of the sensor device 200A.

The management equipment into which the sensor device 200A is introduced may include an RF module. When the sensor device 200A is introduced, the RF module may output RF power, and the RF energy harvester 241A may generate power using the RF power. The battery 242A may be charged by the power generated by the RF energy harvester 241A, and the controller 220 and the wireless communication unit 230 may operate.

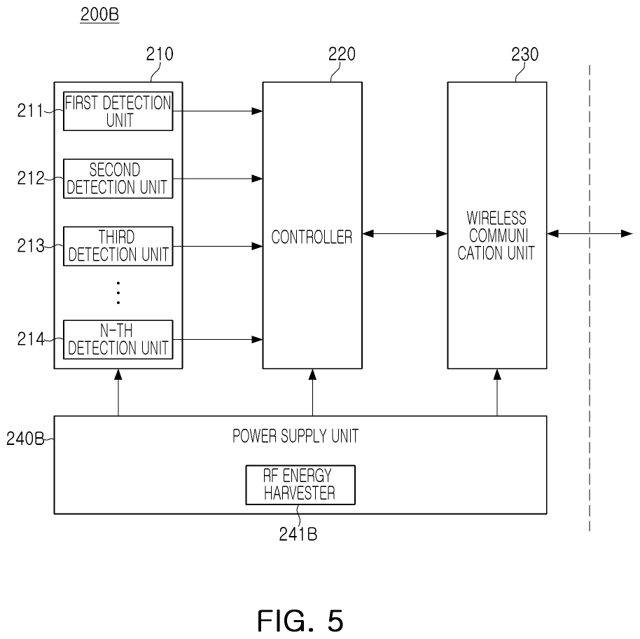

Next, referring to FIG. 5, a sensor device 200B according to an embodiment of the present inventive concept may include a plurality of detection units 211 to 214: 210, a controller 220, a wireless communication unit 230, a power supply unit 240B, and the like. Configurations and operations of the plurality of detection units 211 to 214: 210, the controller 220, and the wireless communication unit 230 may be similar to those described above with reference to FIG. 3.

In the sensor device 200B according to an embodiment illustrated in FIG. 5, the power supply unit 240B may include an RF energy harvester 241B. Since the power supply unit 240B does not include a separate battery, while the sensor device 200B is introduced into the semiconductor processing apparatus and the plurality of detection units 210 collects detection information from plasma, power necessary for the operation of the plurality of detection units 210 and the controller 220 may be directly supplied from the RF energy harvester 241B.

The sensor device 200B drawn out of the semiconductor processing apparatus may be received in the FOUP or the like and transferred to other management equipment. When the sensor device 200B is introduced into the management equipment, the management equipment may receive detection information collected by the sensor device 200B or characteristic data generated by the controller 220 from the detection information through the wireless communication unit 230 of the sensor device 200B. The RF energy harvester 241B may produce power necessary for the operation of the controller 220 and the wireless communication unit 230 of the sensor device 200B. The RF module included in the management equipment may output RF power when the sensor device 200B is accommodated in the management equipment, and the RF energy harvester 241A may produce power using the RF power output by the RF module of the management equipment. The controller 220 and the wireless communication unit 230 may operate by the power produced by the RF energy harvester 241B, and the management equipment may receive the detection information or the characteristic data from the sensor device 200B.

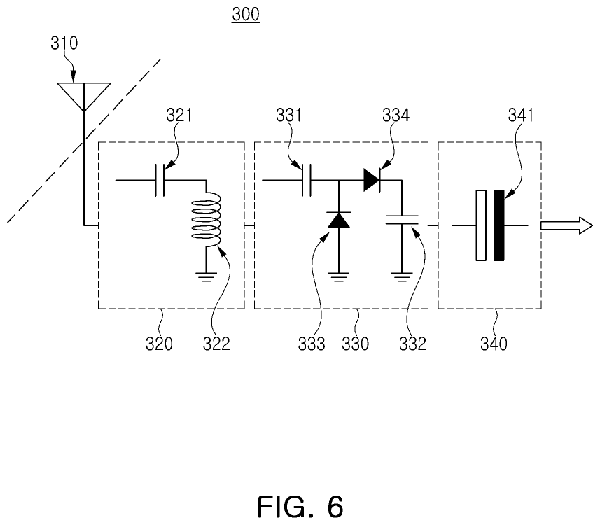

FIG. 6 is a diagram schematically illustrating an RF energy harvester included in a sensor device according to an embodiment of the present inventive concept.

Referring to FIG. 6, an RF energy harvester 300 according to an embodiment of the present inventive concept may include an antenna 310, a matching circuit 320, a rectifier circuit 330, and a storage circuit 340. The antenna 310 may be implemented with a coil pattern or the like and may convert an RF signal into an AC voltage. The RF energy harvester 300 according to an embodiment of the present inventive concept may be mounted in a sensor device and convert RF power applied to a semiconductor processing apparatus into which the sensor device is introduced into an AC voltage.

The matching circuit 320 is a circuit for impedance matching, and may reduce resistance loss so that maximum power corresponding to the AC voltage generated by the antenna 310 may be delivered to the rectifier circuit 330 and the storage circuit 340. The matching circuit 320 may be implemented as a resonator circuit including a matching capacitor 321 and a matching inductor 322.

The rectifier circuit 330 may include a first capacitor 331, a second capacitor 332, a first rectifier diode 333, and a second rectifier diode 334. The first capacitor 331 may be connected to an output terminal of the matching circuit 320, and the first rectifier diode 333 may be connected between a ground node and the first capacitor 331. The second capacitor 332 may be connected to the ground node, and the second rectifier diode 334 may be connected between the first capacitor 331 and the second capacitor 332. Considering that the frequency of the RF power detected by the antenna 310 is very high, the first rectifier diode 333 and the second rectifier diode 334 may be implemented with Schottky barrier diodes capable of fast switching.

The rectifier circuit 330 may convert the AC voltage that has passed through the matching circuit 320 into a DC voltage. When the AC voltage passing through the matching circuit 320 is in a forward direction, a current path may be formed with the first capacitor 331, the second rectifier diode 334, and the second capacitor 332, and the second capacitor 332 may be charged. When the AC voltage is reversed, the charge charged in the second capacitor 332 is not discharged by the second rectifier diode 334, and a current path including the first rectifier diode 333 and the first capacitor 331 may be formed.

The storage circuit 340 is a circuit storing power of the DC voltage generated by the rectifier circuit 330 and may include at least one storage capacitor 341. The power stored in the storage capacitor 341 may be output as an energy source, and in an embodiment of the present inventive concept, the power stored in the storage circuit 340 may be used to charge the battery included in the sensor device together with the RF energy harvester 300. Alternatively, power necessary for the operation of a plurality of detection units or the controller included in the sensor device may be directly supplied from the storage circuit 340.

According to embodiments, the sensor device may include a plurality of RF energy harvesters 300. For example, by providing two or more RF energy harvesters 300 producing power in response to RF signals of the same frequency, power necessary for the operation of the sensor device may be more stably produced. Alternatively, versatility of the sensor device may be improved by including two or more RF energy harvesters producing power in response to RF signals of different frequencies.

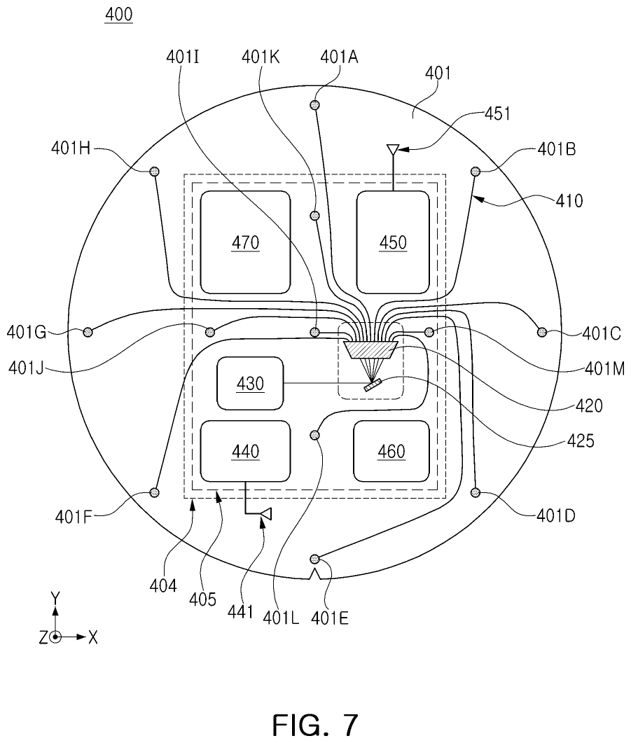

FIGS. 7 to 11 are diagrams schematically illustrating sensor devices according to embodiments of the present inventive concept.

Referring first to FIGS. 7 to 10, a sensor device 400 according to an embodiment of the present inventive concept may include an upper substrate 401 and a lower substrate 402. A space is formed between the upper substrate 401 and the lower substrate 402, and components necessary for the operation of the sensor device 400 may be disposed in the space. Each of the upper substrate 401 and the lower substrate 402 may have a shape, such as a semiconductor wafer, a mask substrate, or a mother substrate for a display.

The sensor device 400 according to the embodiment described above with reference to FIGS. 7 to 10 may collect the intensity of light emitted from plasma as detection information to generate characteristic data representing the uniformity of plasma. To this end, the upper substrate 401 may include a plurality of light receiving regions 401A to 401M receiving light emitted from the plasma, and the number of the plurality of light receiving regions 401A to 401M may be variously modified according to embodiments.

Each of the plurality of light receiving regions 401A to 401M may be formed on the upper substrate 401 and may be formed as regions having relatively high light transmittance compared to other peripheral regions. The plurality of light receiving regions 401A to 401M may be formed in different positions of the upper substrate 401, and thus, when plasma is formed on the sensor device 400, light emitted from different positions of plasma may be incident on the plurality of light receiving regions 401A to 401M.

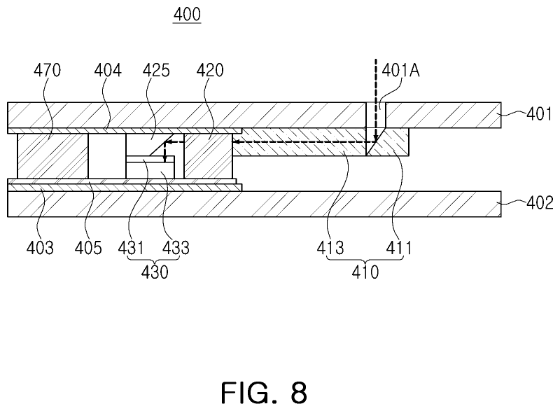

The sensor device 400 may include a plurality of optical members 410, a selection element 420, a spectrum sensor 430, power supply units 440 and 450, a wireless communication unit 460, a controller 470, and the like. Referring to FIG. 8, each of the plurality of optical members 410 may include a light receiving optical system 411 and a light guide 413. The light receiving optical system 411 may include a mirror disposed below one of the plurality of light receiving regions 401A to 401M, and light reflected from the mirror may be incident on the light guide 413. The light guide 413 may transfer light reflected by the light receiving optical system 411 to the selection device 420 and may include, for example, an optical fiber.

The selection element 420 may determine one selection optical member among the plurality of optical members 410 and output light transmitted through the selection optical member to the reflective mirror 425. The reflective mirror 425 may change a path of light output from the selection element 420 and transfer light to the spectrum sensor 430.

The spectrum sensor 430 may include a wavelength selector 431 and a photodetector 433, and the wavelength selector 431 may be disposed in a path along which light travels from the reflective mirror 425 to the photodetector 433. For example, the wavelength selector 431 may include a plasmonic filter, a grating structure, or a micro-resonator using thin film interference principles. When the wavelength selector 431 includes a plasmonic filter, the wavelength selector 431 may include a plurality of filter regions allowing light to be transmitted therethrough in different unit wavelength bands. For example, the plurality of filter regions may be arranged in one direction parallel to an upper surface of the upper substrate 401. In addition, the photodetector 433 may also include a plurality of photodetection elements arranged in one direction to detect the intensity of light in each of a plurality of unit wavelength bands.

According to embodiments, the plurality of optical members 410, the selection device 420, and the spectrum sensor 430 may be implemented in other structures. For example, the wavelength selector 431 and the photodetector 433 may be individually connected to each of the plurality of optical members 410. In this case, the selection element 420 may be omitted, and the controller 470 may control the wavelength selector 431 so that the photodetector 433 detects the intensity of light in a specific wavelength band.

The intensity of light detected by the spectrum sensor 430 may be transferred to the controller 470, and the controller 470 may generate characteristic data representing characteristics of plasma using the intensity of light detected by the spectrum sensor 470. For example, the controller 470 may generate characteristic data by matching the intensity of light according to a wavelength band to each of the plurality of light receiving regions 401A to 401M. Accordingly, raw data including intensities of light detected in a plurality of unit wavelength bands may be generated for each of the plurality of light receiving regions 401A to 401M. According to embodiments, the controller 470 may generate characteristic data representing the uniformity of plasma using the intensity of light.

In an embodiment illustrated in FIGS. 7 to 10, the controller 470 may be mounted on a circuit board 405 together with the selection element 420, the spectrum sensor 430, the power supply units 440 and 450, and the wireless communication unit 460. The intensity of light detected by the spectrum sensor 430 may be transferred to the controller 470 through the circuit board 405, and the controller 470 may control the operation of the selection element 420 and the spectrum sensor 430 through the circuit board 405. In the embodiment described above with reference to FIGS. 7 to 10, the circuit board 405 may have a shape different from that of the upper substrate 401 and the lower substrate 402.

Referring to FIGS. 8 to 10, a lower protective (i.e., shielding) film 403 may be disposed between the lower substrate 402 and the circuit board 405, and an upper protective (i.e., shielding) film 404 may be attached to a lower surface of the upper substrate 401. Each of the lower protective film 403 and the upper protective film 404 may protect the selection element 420, the spectrum sensor 430, the wireless communication unit 460, the controller 470, and the like. A strong magnetic field may be formed in an internal space of the semiconductor processing apparatus in which plasma is formed, and the temperature may also be very high. Each of the lower protective film 403 and the upper protective film 404 may be formed of permalloy or the like having high magnetic field shielding performance. Each of the lower protective film 403 and the upper protective film 404 may have an area larger than that of the circuit board 405.

Power necessary for the operation of the selection element 420, the spectrum sensor 430, the wireless communication unit 460, and the controller 470 may be supplied by the power supply units 440 and 450. Each of the power supply units 440 and 450 may include an RF energy harvester. For example, the first power supply unit 440 may include a first battery and a first RF energy harvester, and the second power supply unit 450 may include a second battery and a second RF energy harvester.

Structures of each of the first RF energy harvester and the second RF energy harvester may be similar to those described above with reference to FIG. 6. In an embodiment, an antenna included in the first RF energy harvester may generate an AC voltage in response to the first RF power of the first frequency band. An antenna included in the second RF energy harvester may generate an AC voltage in response to second RF power of a second frequency band, different from the first frequency band. In this manner, by providing the sensor device 400 with a plurality of RF energy harvesters producing power in response to RF power of different frequency bands, the sensor device 400 may be used to control various semiconductor processing apparatuses using RF power of different frequency bands.

The sensor device 400 may produce power by itself while plasma is formed in the semiconductor processing apparatus by the RF energy harvester. Therefore, a low-capacity battery included in each of the power supply units 440 and 450 may be adopted, or the battery may be omitted, and problems in which the battery is damaged by the internal environment of the semiconductor processing apparatus having a state close to vacuum and the reliability of the sensor device 400 is deteriorated may be prevented.

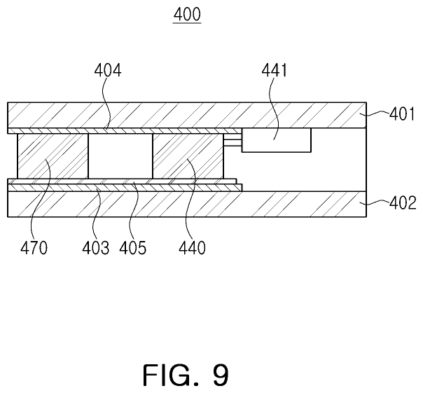

Referring to FIG. 9, a first antenna 441 connected to the first RF energy harvester included in the first power supply unit 440 may be disposed outside a lower shielding film 403 and an upper shielding film 404. Accordingly, the first antenna 441 may be exposed more to RF power, and power production efficiency of the first RF energy harvester may increase. The matching circuit, the rectifier circuit, the storage circuit, and the like of the first RF energy harvester, excluding the first antenna 441, may be arranged to overlap the lower shielding film 403 and the upper shielding film 404.

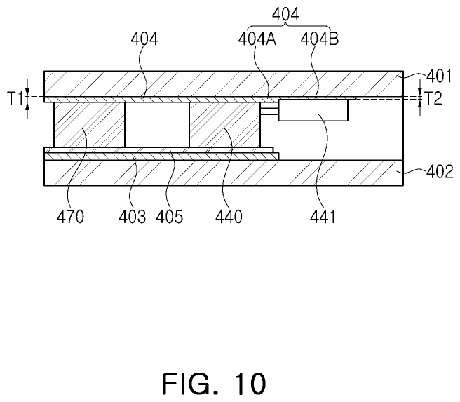

The arrangement form of the first antenna 441 may vary according to embodiments. In the embodiment illustrated in FIG. 10, the first antenna 441 included in the sensor device 400A may be disposed in a position overlapping the upper shielding film 404 (i.e., the upper shielding film 404 overlaps or covers the first antenna 441 such that the first antenna 441 is exposed to a reduced amount of RF power). The upper shielding film 404 may include a first region 404A and a second region 404B, and the first antenna 441 may overlap the second region 404B (i.e., the second region 404B of the upper shielding film 404 overlaps or covers the first antenna 441 such that the first antenna 441 is exposed to a reduced amount of RF power). The first region 404A may overlap the selection element 420, the spectrum sensor 430, the wireless communication unit 460, the controller 470 and the battery of the power supply unit 440 (i.e., the first region 404A of the upper shielding film 404 overlaps or covers the selection element 420, the spectrum sensor 430, the wireless communication unit 460, the controller 470 and the battery of the power supply unit 440 such that the selection element 420, the spectrum sensor 430, the wireless communication unit 460, the controller 470 and the battery of the power supply unit 440 are shielded entirely from or exposed to a reduced amount of RF power).

As illustrated in FIG. 10, the first region 404A may have a first thickness and the second region 404B may have a second thickness, and the first thickness may be greater than the second thickness. Accordingly, the power production efficiency of the first RF energy harvester may increase by relatively strongly exposing the first antenna 441 to RF power compared to other elements.

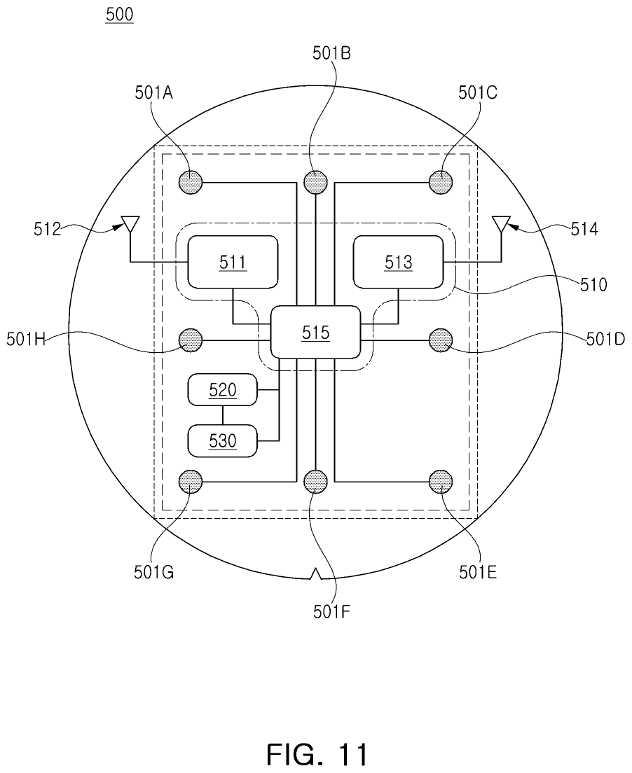

Next, referring to FIG. 11, a sensor device 500 according to an embodiment of the present inventive concept may include an upper substrate and a lower substrate and a plurality of detection units 501A to 501H, a power supply unit 510, a controller 520, a data storage 530, and the like disposed in a space between the upper substrate and the lower substrate. The power supply unit 510 may include a first RF energy harvester 511, a second RF energy harvester 513, and a battery 515. The first RF energy harvester 511 may include a first antenna 512, and the second RF energy harvester 513 may include a second antenna 514.

As described above, the first antenna 512 may generate an AC voltage in response to first RF power of a first frequency band, and the second antenna 514 may generate an AC voltage in response to second RF power of a second frequency band, different from the first frequency band. The first antenna 512 and the second antenna 514 may be disposed to the outside of (i.e., are not shielded or covered by) the protective film 504 and are exposed to RF power. The first RF energy harvester 511 and the second RF energy harvester 513 may charge the battery 515.

In the embodiment illustrated in FIG. 11, each of the plurality of detection units 501A to 501H may include a sensor detecting a temperature or vibrations of the plasma formed in an internal space of a semiconductor processing apparatus into which the sensor device 500 is introduced. For example, each of the plurality of detection units 501A to 501H may include a sensor for detecting the temperature of plasma, and power necessary for the operation of each of the plurality of detection units 501A to 501H may be supplied from the battery 515. The battery 515 may also supply power necessary for the operation of the controller 520 and the data storage 530.

The controller 520 may generate characteristic data representing a temperature distribution of plasma formed on the sensor device 500 by using temperature information collected by each of the plurality of detection units 501A to 501H. The controller 520 may generate characteristic data representing a temperature distribution over time using the temperature information collected by each of the plurality of detection units 501A to 501H at different times, and store the characteristic data in the data storage 530. The data storage 530 may be implemented as a memory having non-volatile characteristics.

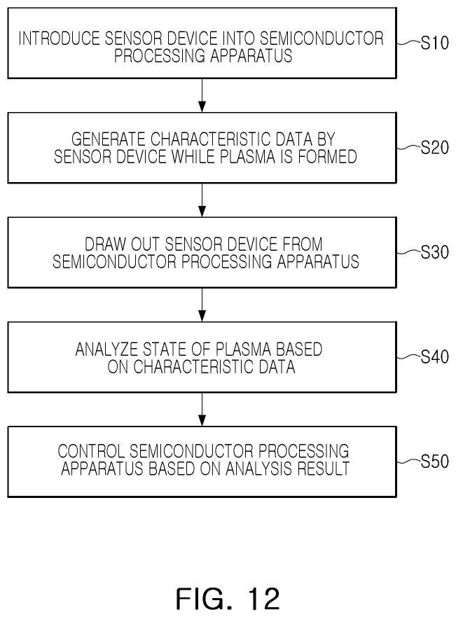

FIG. 12 is a flowchart illustrating a method for controlling a semiconductor process according to an embodiment of the present inventive concept.

Referring to FIG. 12, a method for controlling a semiconductor process according to an embodiment of the present inventive concept may start by introducing a sensor device into a semiconductor processing apparatus (S10). The semiconductor processing apparatus may be an apparatus for performing a semiconductor process, such as deposition and etching, by forming plasma in a space inside a chamber.

The sensor device may have a structure according to at least one of the embodiments described above. For example, when a processing target introduced into the semiconductor processing apparatus is a wafer, the sensor device may be implemented as one of the sensor devices described above with reference to FIGS. 7 to 12. However, according to embodiments, when the processing target introduced into the semiconductor processing apparatus is a mother substrate for a display, the sensor device may have the same shape as that of the mother substrate for a display, instead of a wafer.

The sensor device introduced into the semiconductor processing apparatus may be placed on the electrostatic chuck and fixed to the electrostatic chuck by a Coulomb force generated from a chuck voltage supplied to the electrostatic chuck. When the sensor device is fixed to the electrostatic chuck, plasma may be formed in an internal space of the chamber of the semiconductor processing apparatus. For example, plasma may be formed by RF power supplied to bias electrodes arranged inside the chamber of the semiconductor processing apparatus. Characteristics of RF power, for example, a frequency band and/or power level, may vary depending on a process to be performed with the semiconductor processing apparatus.

The thickness and density of the plasma generated by the RF power may be determined by preset control variables for the semiconductor processing apparatus. For example, the control variables may include RF power, a distance between the bias electrodes facing up and down inside the chamber, temperature and pressure inside the chamber, and the like.

When plasma is formed inside the chamber of the semiconductor processing apparatus, the sensor device may operate to generate characteristic data (S20). The sensor device may include a plurality of detection units collecting a temperature of plasma, the intensity of light emitted from the plasma, and the like as detection information and a controller generating characteristic data representing characteristics of plasma using the detection information. For example, in the process of stabilizing particles, such as ions, included in plasma, light of a specific wavelength band is emitted, and the wavelength band may vary depending on chemical species. The sensor device may separately detect the intensity of light emitted from plasma according to a wavelength band, and the controller may generate characteristic data representing the uniformity of plasma using the intensity of light according to the wavelength band.

Power necessary for the operation of the plurality of detection units and the controller may be supplied from a battery included in the sensor device and/or an RF energy harvester included in the sensor device. The RF energy harvester may include an antenna converting RF power into an AC voltage and a voltage generating circuit converting the AC voltage generated by the antenna into a DC voltage. The voltage generating circuit may include a plurality of circuits for impedance matching, rectification, and energy storage.

According to embodiments, the DC voltage generated by the RF energy harvester may be directly supplied as power to the plurality of detection units and/or the controller or may be used to charge a battery. Therefore, the sensor device may be implemented with a small-capacity battery, thereby reducing the risk of battery damage, or the sensor device may be implemented with a structure that does not include a battery.

When the sensor device generates characteristic data, the sensor device may be drawn out of (i.e., removed from) the semiconductor processing apparatus by a transfer robot connected to the semiconductor processing apparatus (S30). The sensor device removed from the chamber may be mounted on a FOUP or the like and transferred to another management location. According to embodiments, while mounted on the FOUP, the sensor device may receive power from the FOUP to charge the battery or may transmit characteristic data externally through a wireless communication unit inside the sensor device. The characteristic data may be transmitted to a server or the like controlling an overall system including the semiconductor processing apparatus.

According to embodiments, the sensor device may be mounted on the FOUP and moved to separate management equipment. The management equipment may perform an operation, such as receiving characteristic data from the sensor device and analyzing the characteristic data to adjust a control variable of the semiconductor processing apparatus or transmitting the characteristic data to a server. If a separate battery is not included in the sensor device, the management equipment may include an RF module outputting RF power so that the RF energy harvester may generate power to execute an operation of fetching the characteristic data from the sensor device. For example, the RF power output from the RF module included in the management equipment may have the same characteristics as those of the RF power applied to the bias electrodes in the semiconductor processing apparatus in which the sensor device is introduced in step S10.

The management equipment receiving the characteristic data may analyze a state of plasma based on the characteristic data (S40). In an embodiment, the characteristic data may include image data representing the intensity of light emitted from plasma in the internal space of the chamber by location and wavelength band. A control device may analyze a thickness and density of the plasma formed inside the chamber using the characteristic data, and control the semiconductor processing apparatus according to a result (S50). For example, when the density of plasma is not uniform, the control device may increase or decrease the distance between the bias electrodes in the chamber of the semiconductor processing apparatus.

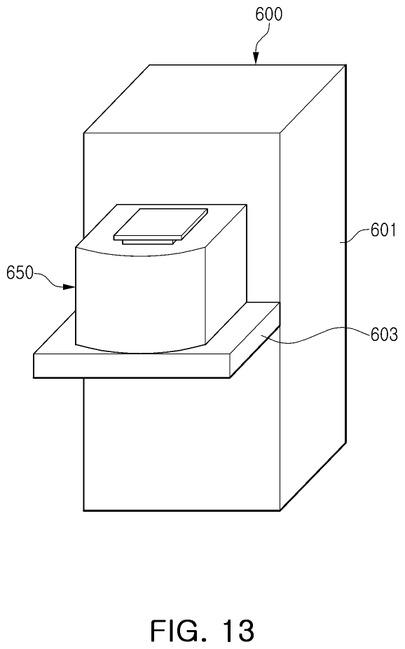

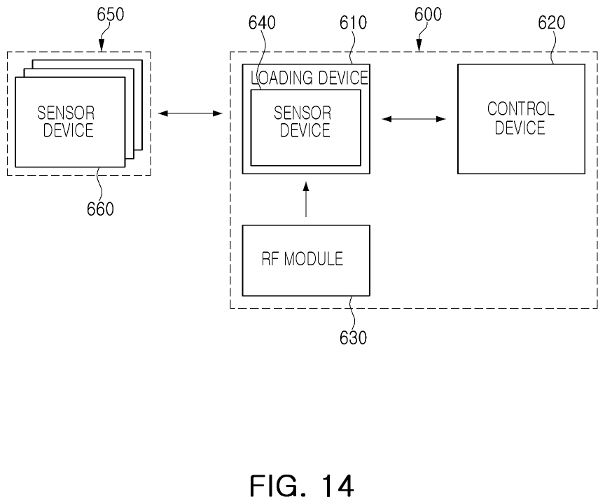

FIGS. 13 and 14 are diagrams illustrating an operation of a sensor device according to an embodiment of the present inventive concept.

FIGS. 13 and 14 may be diagrams schematically illustrating a management equipment 600 in which a sensor device, which is introduced into a semiconductor processing apparatus and generates characteristic data, is housed in a FOUP 650 and transferred. First, referring to FIG. 13, the management equipment 600 may include a housing 601 and a loading port 603 attached to the housing 601 and providing a receiving space in which the FOUP 650 may be seated.

When the FOUP 650 in which a sensor device is received is seated on the loading port 603, at least one sensor device may be removed from the FOUP 650 and introduced into the management equipment 600. Referring to FIG. 14, sensor devices 660 may be received in the FOUP 650, and one sensor device 640 may be selectively loaded into the management equipment 600 by a loading device 610.

The management equipment 600 may include the control device 620 and an RF module 630 in addition to the loading device 610. When the loading device 610 brings one sensor device 640 among the sensor devices 660 accommodated in the FOUP 650 into the management equipment 600, the RF module 630 may operate. The sensor device 640 may include an RF energy harvester, and the RF energy harvester may generate power necessary for the operation of the sensor device 640 using RF power output from the RF module 630.

The control device 620 may receive characteristic data from the sensor device 640 through a wired/wireless communication method. The characteristic data may be data generated by introducing the sensor device 640 into the semiconductor processing apparatus and collecting, as detection information, temperature of the plasma, vibrations of the plasma, the intensity of light emitted from the plasma, and the like. The control device 620 may analyze characteristics of the plasma generated in the semiconductor processing apparatus using the characteristic data, generate a command for controlling the semiconductor processing apparatus based on the analysis, and transfer the generated command to the semiconductor processing apparatus. Therefore, the characteristics including the uniformity of the plasma may be improved and the yield of the semiconductor process may be improved.

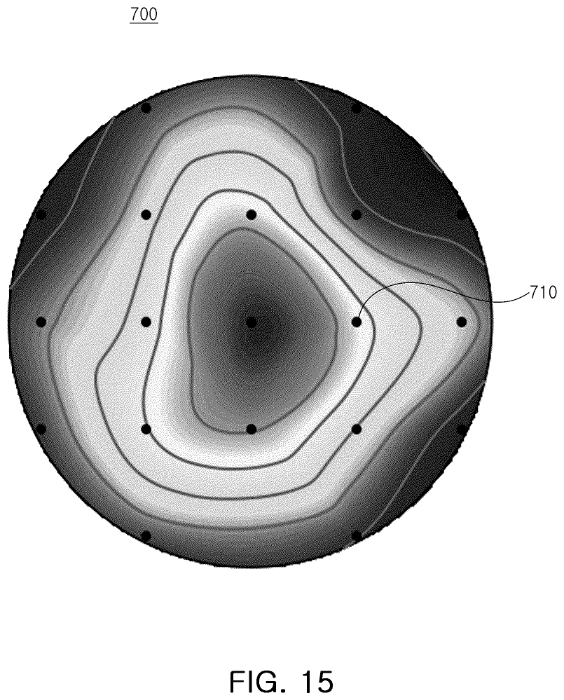

FIG. 15 is a diagram schematically illustrating characteristic data generated by a sensor device according to an embodiment of the present inventive concept.

In the embodiment illustrated in FIG. 15, characteristic data 700 may be generated in the form of image data. A two-dimensional plane on which the characteristic data 700 is expressed may correspond to a plane parallel to an upper surface of an electrostatic chuck on which the sensor device and a processing target are seated, and the characteristic data 700 may express difference of the intensities of light corresponding to a specific wavelength band, in the form of an image. In an embodiment, the characteristic data 700 may be image data generated by the intensity of light detected in a plurality of light receiving regions 710 defined in the sensor device.

Referring to FIG. 15, the intensity of light may appear relatively strong toward the center of the plane parallel to the upper surface of the electrostatic chuck and may appear relatively weak toward the periphery of the plane. From such characteristic data, a control device, such as a server controlling a system including the semiconductor processing apparatus, may determine that the plasma has an uneven distribution as being higher density in the center of the plasma and lower density in the periphery of the plasma formed in the space above the electrostatic chuck. Accordingly, the control device may determine that the uniformity of the plasma is deteriorated (i.e., that the plasma is non-uniform).

The control device may adjust the control variable of the semiconductor processing apparatus based on the characteristics, such as the density of the plasma determined by referring to the characteristic data 700. For example, as illustrated in FIG. 15, when it is determined that the density of plasma is high in the center and low in the periphery, the control device may change the distance between the bias electrodes mounted in the chamber of the semiconductor processing apparatus.

For example, prior to actually performing semiconductor processing, the sensor device introduced into the semiconductor processing apparatus may generate the characteristic data 700 as described above with reference to FIG. 15 in each of a plurality of wavelength bands. As described above, the wavelength band of light emitted from plasma may vary depending on the chemical species. Therefore, characteristics of various plasmas generated by different types of gases may be analyzed with the sensor device according to an embodiment of the present inventive concept.

The control device receiving the characteristic data 700 from the sensor device may determine the characteristics of plasma only with a relative distribution represented by the characteristic data 700 or determine characteristics, such as the uniformity of plasma, by comparing the characteristic data 700 with reference data generated in advance according to an embodiment. For example, the characteristic data 700 may be compared with the reference data to determine whether the intensity of light emitted from the plasma is stronger than a reference intensity, and RF power supplied to the semiconductor processing apparatus may be increased or decreased based on the determination.

Also, as described above, the characteristic data 700 may be generated to indicate a temperature distribution, not the intensity of light. In this case, the sensor device may include a temperature sensor for measuring temperature, instead of the photodetector for detecting the intensity of light.

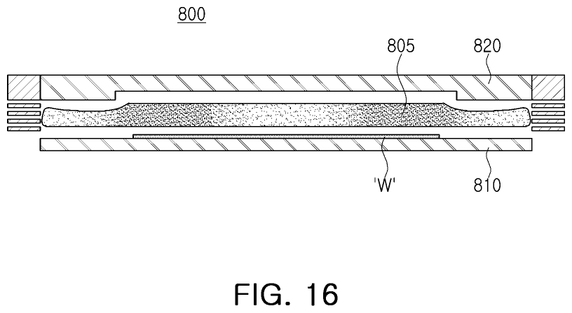

FIGS. 16 to 18 are diagrams illustrating an operation of a semiconductor processing apparatus according to an exemplary embodiment of the present inventive concept.

FIGS. 16 to 18 may be diagrams provided to describe an operation of controlling a semiconductor processing apparatus 800 by a control device, such as a server, that controls a system including a semiconductor processing apparatus, with reference to characteristic data. The characteristic data referred to by the control device may be data generated based on detection information collected from plasma by a sensor device introduced into the semiconductor processing apparatus 800 prior to actually performing semiconductor processing using plasma in the semiconductor processing apparatus 800.

Referring to FIGS. 16 to 18, the semiconductor processing apparatus 800 may include a first bias electrode 810 and a second bias electrode 820, and a plasma 805 may be generated in a space therebetween. The plasma 805 may be formed on the wafer W to be processed.

FIG. 16 may be a diagram illustrating a case in which a distance between the first bias electrode 810 and the second bias electrode 820 is small. When the distance between the first bias electrode 810 and the second bias electrode 820 is small, the density of the plasma 805 may be uneven. For example, referring to FIG. 16, the density of the plasma 805 may appear low in the center and the periphery of the space above the wafer W, and the density of the plasma 805 may appear high in the space therebetween.

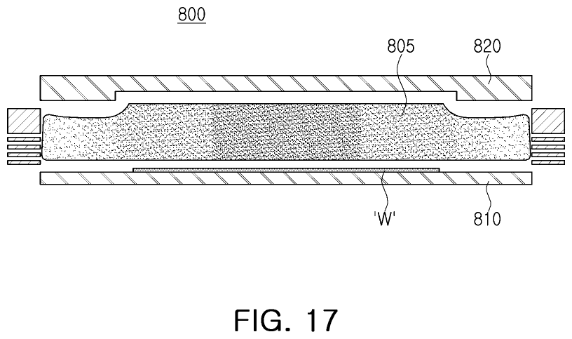

FIG. 17 may be a diagram illustrating a case in which the distance between the first bias electrode 810 and the second bias electrode 820 is set to be large. As the distance between the first bias electrode 810 and the second bias electrode 820 widens, the density of the plasma 805 may increase toward the center of the wafer W and decrease toward the periphery.

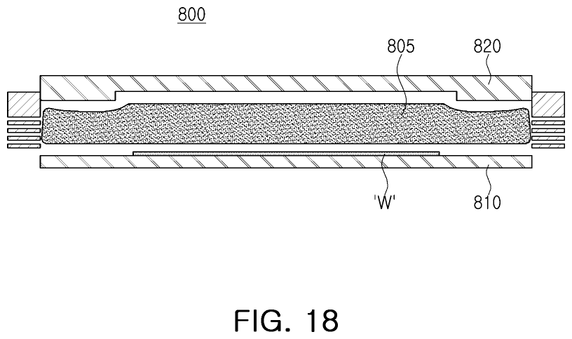

FIG. 18 may be a diagram illustrating a case in which the distance between the first bias electrode 810 and the second bias electrode 820 is appropriately set. In the embodiment illustrated in FIG. 18, the density of the plasma 805 may appear to be even in the space above the wafer W. As described above with reference to FIGS. 16 to 18, the density of the plasma 805 according to the position in the space above the wafer W may vary according to the distance between the first bias electrode 810 and the second bias electrode 820.

In an embodiment of the present inventive concept, prior to introducing the wafer W to actually perform semiconductor processing, it may be determined whether the distance between the first bias electrode 810 and the second bias electrode 820 is appropriately set by introducing the sensor device, instead of the wafer W, and forming the plasma 805. As described above, the sensor device may collect, as detection information, the intensities of light emitted from different locations of a space in which the plasma 805 is formed.

When the distance between the first bias electrode 810 and the second bias electrode 820 is set as shown in FIG. 16, the intensity of light may be detected to be small in a position close to the center of the sensor device and the intensity of light may be detected to be large in a position close to the periphery of the sensor device. When the distance between the first bias electrode 810 and the second bias electrode 820 is set as shown in FIG. 17, the intensity of light may be detected to be large in the position close to the center of the sensor device and the intensity of light may be detected to be small in the position close to the periphery of the sensor device.

The control device of the semiconductor processing apparatus may adjust the distance between the first bias electrode 810 and the second bias electrode 820 by referring to the intensity of light detected by the sensor device from a plurality of positions. For example, when the intensity of light is detected to be relatively stronger in a position close to the center of the sensor device, the control device may lower the position of the second bias electrode 820 to reduce the distance between the first bias electrode 810 and the second bias electrode 820. In addition, when the intensity of light is detected to be relatively stronger in a position close to an outer portion of the sensor device, the control device may raise the position of the second bias electrode 820 to increase the distance between the first bias electrode 810 and the second bias electrode 820. In this manner, by adjusting the distance between the first bias electrode 810 and the second bias electrode 820 based on the intensity of light collected by the sensor device, the plasma 805 may be formed with even density as shown in FIG. 18 during the actual semiconductor processing by introducing the wafer W, and the yield of the semiconductor process may be improved.

According to an embodiment of the present inventive concept, the sensor device having the same shape as that of a processing target, such as a wafer, a mask, or a mother substrate for a display is provided, and the sensor device may be introduced into the semiconductor processing apparatus to collect characteristic data to analyze the characteristics of plasma. The power necessary for the operation of the sensor device may be produced by the RF energy harvester included in the sensor device, and thus, the battery inside the sensor device may be implemented with a small capacity or the battery may be omitted, so that problems that may arise due to the battery in extreme environments may be reduced and the reliability of the sensor device may be improved.

While example embodiments have been illustrated and described above, it will be apparent to those skilled in the art that modifications and variations could be made without departing from the scope of the present inventive concept as defined by the appended claims.

What is claimed is:

1. A sensor device comprising:
a first substrate;
a second substrate on the first substrate;
a plurality of detection units between the first substrate and the second substrate, wherein each of the plurality of detection units are configured to collect detection information from plasma formed in a space above the second substrate;
a controller configured to generate characteristic data representing characteristics of the plasma based on the detection information collected by the plurality of detection units; and
a power supply unit comprising a radio frequency (RF) energy harvester configured to produce power for operation of at least one of the plurality of detection units and the controller from RF power used to form the plasma.

2. The sensor device of claim 1, wherein the RF energy harvester comprises an antenna configured to receive RF power, a rectifier circuit configured to convert an AC voltage corresponding to the RF power into a DC voltage, a matching circuit connected between the antenna and the rectifier circuit, and a storage circuit configured to store power corresponding to the DC voltage.

3. The sensor device of claim 2, wherein the matching circuit comprises a matching capacitor and a matching inductor, and
the rectifier circuit comprises a first capacitor connected to an output terminal of the matching circuit, a second capacitor connected between the first capacitor and a ground node, a first rectifier diode connected between the first capacitor and the ground node, and a second rectifier diode connected between the first capacitor and the second capacitor.

4. The sensor device of claim 2, further comprising:
a first shielding film attached to the second substrate and positioned so as to cover the controller.

5. The sensor device of claim 4, wherein the antenna is not covered by the first shielding film.

6. The sensor device of claim 4, wherein
the first shielding film comprises a first region having a first thickness and a second region having a second thickness that is smaller than the first thickness, and
the antenna is covered by the second region of the first shielding film.

7. The sensor device of claim 4, wherein the matching circuit, the rectifier circuit, and the storage circuit are covered by the first shielding film.

8. The sensor device of claim 1, further comprising:
a circuit board on an first surface of the first substrate, wherein the controller and the power supply unit are mounted on the circuit board.

9. The sensor device of claim 8, further comprising:
a second shielding film between the circuit board and the first substrate.

10. The sensor device of claim 1, wherein the power supply unit comprises a battery configured to be charged by the power produced by the RF energy harvester and configured to output a power supply voltage to at least one of the plurality of detection units and the controller.

11. The sensor device of claim 10, wherein the power supply unit comprises a charging circuit that is separate from the RF energy harvester, wherein the charging circuit is configured to charge the battery.

12. The sensor device of claim 1, wherein the detection information that each of the plurality of detection units is configured to collect comprises at least one of a temperature of the plasma, vibrations of the plasma, and an intensity of light emitted from the plasma.

13. The sensor device of claim 1, further comprising:
a wireless communication unit configured to provide communication between the controller and an external device, and wherein the wireless communication unit is powered by power generated by the power supply unit.

14. The sensor device of claim 1, wherein the RF energy harvester comprises a first RF energy harvester configured to produce the power using a first RF power of a first frequency band, and a second RF energy harvester configured to produce the power using a second RF power of a second frequency band that is different from the first frequency band.

15. A sensor device comprising:
a first substrate;
a second substrate on the first substrate;
a coil pattern between the first substrate and the second substrate, wherein the coil pattern is configured to convert radio frequency (RF) power for forming plasma on the second substrate into an AC voltage;
a voltage generating circuit connected to the coil pattern and configured to convert the AC voltage into a DC voltage; and
a controller configured to receive the DC voltage output from the voltage generating circuit and generate characteristic data representing characteristics of the plasma.

16. The sensor device of claim 15, further comprising:
a first shielding film attached to a first surface of the second substrate and configured to cover the controller, wherein the first shielding film comprises permalloy,
wherein the coil pattern is not covered by the first shielding film.

17. The sensor device of claim 15, wherein the characteristic data comprises at least one of a temperature distribution and a density distribution of the plasma.

18. The sensor device of claim 15, wherein the controller receives the DC voltage from the voltage generating circuit without a battery.

19. The sensor device of claim 15, wherein the coil pattern includes a first coil pattern converting a first RF power of a first frequency, and a second coil pattern converting a second RF power of a second frequency different from the first frequency.

20. A sensor device comprising:
a pair of substrates providing a space therebetween;
a plurality of detection units disposed in the space, wherein each of the plurality of detection units are configured to collect detection information from plasma formed over the pair of substrates;
a controller configured to generate at least one of a temperature distribution and a density distribution of the plasma based on the detection information; and
a power supply unit configured to produce power for operation of the plurality of detection units and the controller by converting a radio frequency (RF) energy for generating the plasma into a DC voltage, and supply the power to the plurality of detection units and the controller without going through a battery.
